(19) United States
(12) Patent Application Publication
(10) Pub. No.: US 2013/0291936 A1
(43) Pub. Date: Nov. 7, 2013

(54) SOLAR CELL

(71) Applicants: Miin-Jang Chen, Taipei City (TW); Hsin-Jui Chen, Taipei City (TW); Wei-Cheng Wang, New Taipei City (TW); Wen-Ching Hsu, Hsinchu (TW)

(72) Inventors: Miin-Jang Chen, Taipei City (TW); Hsin-Jui Chen, Taipei City (TW); Wei-Cheng Wang, New Taipei City (TW); Wen-Ching Hsu, Hsinchu (TW)

(73) Assignees: SINO-AMERICAN SILICON PRODUCTS INC., Hsinchu (TW); Miin Jang Chen, Taipei City (TW)

(21) Appl. No.: 13/858,947

(22) Filed: Apr. 9, 2013

(30) Foreign Application Priority Data
Apr. 9, 2012 (TW) 101112462

(51) Int. Cl. H01L 31/0216

(52) U.S. Cl. CPC H01L 31/02168
USPC 136/256

(57) ABSTRACT

A solar cell is provided. The solar cell includes a substrate, a first electrode, a second electrode, a seed layer, and a plurality of nanorods. The substrate has a first surface and a second surface opposite to each other. A conductive type of a portion of the substrate adjacent to the first surface is first conductive type, and a conductive type of the remaining portion of the substrate is second conductive type. The first electrode is disposed on the first surface. The second electrode is disposed on the second surface. The seed layer is disposed on the first surface. The nanorods are disposed on the seed layer.

### CROSS-REFERENCE TO RELATED APPLICATION

This application claims the priority benefit of Taiwan application serial no. 101112462, filed on Apr. 9, 2012. The entirety of the above-mentioned patent application is hereby incorporated by reference herein and made a part of this specification.

### BACKGROUND OF THE INVENTION

1. Field of the Invention

The invention relates to a solar cell, and more particularly, to a solar cell having lower reflectance toward sunlight.

2. Description of Related Art

The silicon-based solar cells are the most popular solar cells in the industry. The concept of silicon-based solar cells is based on introducing dopants into a high-purity semiconductor material (silicon) in order to form a p-type semiconductor and an n-type semiconductor, and then joining the p-type and n-type semiconductors together. As a result, a p-n junction is formed, in which a built-in electrical field is generated. When sunlight irradiates a semiconductor having a p-n structure, the semiconductor absorbs the energy of photons to produce electron-hole pairs. Under the influence of the built-in electric field, the holes move along the direction of the electric field and the electrons move along the opposite direction, and then flow into the external circuit through the electrodes. A solar cell is thus formed.

In general, the antireflection coating (ARC) plays an important role in the solar cell. One of the key factors in producing a high-efficiency solar cell is that the reflectance of the surface has to be maintained at a very low degree in a wide range of the sunlight spectrum. However, the thickness of the conventional single-layer ARC thin film is one quarter of the incident wavelength, and thus the ARC thin film may produce a low reflectance only in a specific range of incident wavelength. Moreover, because the sunlight incident on the solar cell is generally not at normal incidence, the conventional ARC thin film can not maintain a low reflectance. Therefore, the conventional silicon-based solar cells that use silicon nitride (SiNₓ) as single-layer ARC thin films may only generate electricity about 3.5 hours before and after midday.

FIG. 1 is a cross-sectional schematic diagram of a conventional solar cell 10. Referring to FIG. 1, the conventional solar cell 10 includes a substrate 2, a first electrode 9, and a second electrode 6. The substrate 2 has a first surface 2a and a second surface 2b opposite to each other, wherein a conductive type of a portion 4 of the substrate 2 adjacent to the first surface 2a is n-type, and a conductive type of the remaining portion of the substrate 2 is p-type. The first electrode 9 is disposed on the first surface 2a. The second electrode 6 is disposed on the second surface 2b. Moreover, in the manufacturing process of the solar cell 10, during the annealing process of the second electrode 6, the portion of the substrate 2 adjacent to the second surface 2b has a higher dopant concentration, which is the p+ doping region 8.

However, after the conventional solar cell 10 is exposed to sunlight, the reflectance of light with a wavelength region from 400 nm to 800 nm is about 30% and 42%. As a result, the photoelectric conversion efficiency of the conventional solar cell 10 is not high. Therefore, the further reduction of the reflectance of solar cells to increase the photoelectric conversion efficiency of solar cells is an important research objective.

### SUMMARY OF THE INVENTION

The invention provides a solar cell. The solar cell has lower reflectance and higher photoelectric conversion efficiency.

The invention provides a solar cell. The solar cell includes a substrate, a first electrode, a second electrode, a seed layer, and a plurality of nanorods. The substrate has a first surface and a second surface opposite to each other, wherein a conductive type of a portion of the substrate adjacent to the first surface is first conductive type, and a conductive type of the remaining portion of the substrate is second conductive type. The first electrode is disposed on the first surface. The second electrode is disposed on the second surface. The seed layer is disposed on the first surface. The nanorods are disposed on the seed layer.

In an embodiment of the invention, the material of the substrate is, for instance, silicon wafer, thin-film silicon, gallium arsenide, or copper indium gallium selenide (CuInₓGa₍₁₋ₓ₎Se₂, CIGS).

In an embodiment of the invention, the material of the seed layer is, for instance, zinc oxide (ZnO) or magnesium zinc oxide (MgₓZn₁₋ₓO).

In an embodiment of the invention, the seed layer is composed of, for instance, a zinc oxide layer and a magnesium oxide (MgO) buffer layer, wherein the zinc oxide layer is disposed on the magnesium oxide buffer layer.

In an embodiment of the invention, the material of the nanorods is, for instance, zinc oxide or magnesium zinc oxide.

In an embodiment of the invention, the solar cell further includes a protective layer disposed on the surface of each nanorod.

In an embodiment of the invention, the material of the protective layer is, for instance, Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, CO₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, Po_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{y}N_{Z}, Ti_{X}Hf_{Y}O_{Z}, VO_{X}, WO₃, W₂N, W_{X}N, WS₂, W_{X}C, Y₂O₃, Y₂O₂S, ZnS_{1-X}Se_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, or a mixture thereof.

In an embodiment of the invention, the thickness of the seed layer is, for instance, between 1 Å and 1 μm.

In an embodiment of the invention, the nanorods are arranged in, for instance, an array.

In an embodiment of the invention, the seed layer is formed by, for instance, atomic layer deposition, sputtering, hydrothermal synthesis, sol-gel method, metal-organic chemical vapor deposition, chemical vapor deposition, or electrodeposition.

In an embodiment of the invention, the nanorods are formed by, for instance, hydrothermal synthesis, sol-gel method, metal-organic chemical vapor deposition, chemical vapor deposition, electrodeposition, template method, vapor-liquid-solid method, or vapor phase transport deposition.

In an embodiment of the invention, the protective layer is formed by, for instance, atomic layer deposition.

Based on the above, in the solar cell of the invention, a seed layer is disposed on the first surface, and nanorods are formed on the seed layer. The seed layer and the nanorods are used as an antireflection structure, so that the reflectance of the solar cell is significantly reduced. As a result, the incident light absorbed by the solar cell of the invention may be effectively increased, which improves the photoelectric conversion efficiency.

In order to make the aforementioned features and advantages of the invention more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional schematic diagram of a conventional solar cell.

FIG. 2A to FIG. 2E are cross-sectional schematic diagrams of the manufacturing process of a solar cell of an embodiment of the invention.

FIG. 3A and FIG. 3B are cross-sectional schematic diagrams of a solar cell according to another embodiment of the invention.

FIG. 4 is a diagram of the relationship between the reflectance and the wavelength of incident light of the solar cell of experimental example 1, comparative example 1, and comparative example 2, respectively.

FIG. 5 is an X-ray diffraction spectrum of the solar cell of experimental example 1 and experimental example 2, respectively.

FIG. 6 is a scanning electron microscope image of a solar cell of experimental example 1.

FIG. 7 is a scanning electron microscope image of a solar cell of experimental example 2.

### DESCRIPTION OF THE EMBODIMENTS

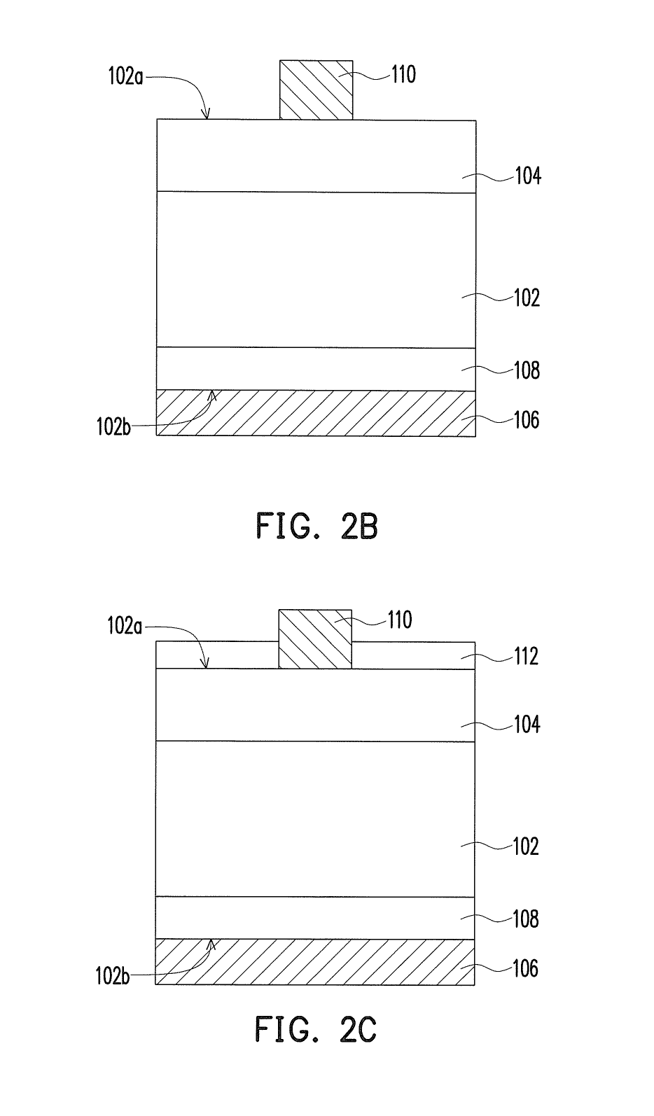

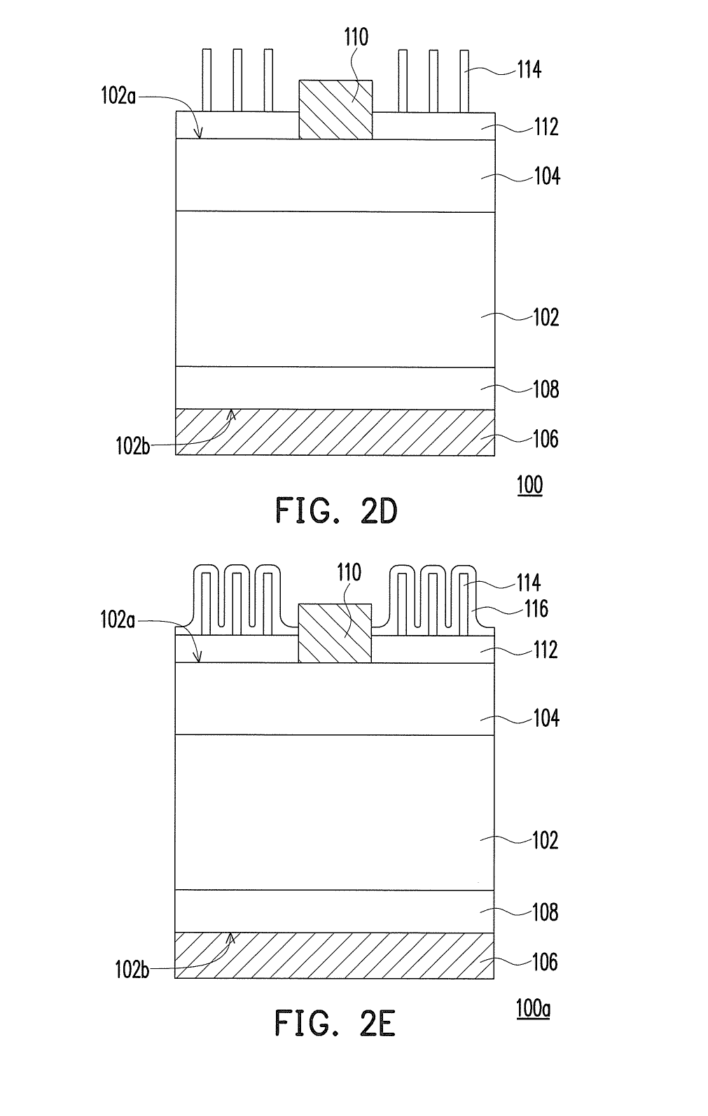

FIG. 2A to FIG. 2E are cross-sectional schematic diagrams of the manufacturing process of a solar cell of an embodiment of the invention. First, referring to FIG. 2A, a substrate 102 is provided. In the present embodiment, the substrate 102 is, for instance, a silicon wafer doped with p-type dopants. However, the invention is not limited thereto. In other embodiments, the material of the substrate 102 may also be, for instance, thin-film silicon, gallium arsenide, copper indium gallium selenide (CuInₓGa₍₁₋ₓ₎Se₂), or other suitable materials. The substrate 102 has a first surface 102a and a second surface 102b opposite to each other. Then, a doping process is performed on the first surface 102a so that the conductive type of the portion 104 of the substrate 102 adjacent to the first surface 102a changes to n-type, and the conductive type of the remaining portion of the substrate 102 remains as p-type in order to form a p-n junction. The doping process is, for instance, phosphorus diffusion process, wherein a phosphorus pentoxide solution is first coated on the substrate 102, and then heat treatment is applied, so that phosphorus is diffused into a portion of the substrate 102.

Then, referring to FIG. 2B, an electrode 106 is fowled on the second surface 102b of the substrate 102. The method of forming the electrode 106 is, for instance, thermal evaporation or screen printing. The material of the electrode 106 is, for instance, aluminum. Moreover, after the electrode 106 is formed, an annealing process is applied to the electrode 106 to improve the adhesion between the electrode 106 and the substrate 102. It should be mentioned that, during the annealing process, a p+ doping region 108 is foamed at the same time in the substrate 102 adjacent to the electrode 106, which generates a back surface field (BSF) effect that significantly reduces the probability of electron-hole recombination at the second surface 102b. Then, an electrode 110 is formed on the first surface 102a of the substrate 102. The material of the electrode 110 is, for instance, silver or aluminum, and the method of forming the electrode 110 is, for instance, thermal evaporation or screen printing.

It should be noted that, in the present embodiment, the portion 104 of the substrate 102 adjacent to the first surface 102a is n-type, and the remaining portion of the substrate 102 is p-type. However, the invention is not limited thereto. Those skilled in the art should understand that, in another embodiment, the portion 104 of the substrate 102 adjacent to the first surface 102a may also be p-type, and that the remaining portion of the substrate 102 is n-type.

Then, referring to FIG. 2C, a seed layer 112 is formed on the first surface 102a of the substrate 102. The material of the seed layer 112 is, for instance, zinc oxide or magnesium zinc oxide. The thickness of the seed layer 112 is, for instance, between 1 Å and 1 μm. The method of forming the seed layer 112 is, for instance, atomic layer deposition, sputtering, hydrothermal synthesis, sol-gel method, metal-organic chemical vapor deposition, chemical vapor deposition, or electrodeposition. The seed layer 112 is not only used to form subsequent nanorods, but may also be used as an antireflection coating layer.

Then, referring to FIG. 2D, nanorods 114 are grown on the seed layer 112 to complete a solar cell 100. In the present embodiment, the nanorods 114 are arranged in, for instance, an array. The material of the nanorods 114 is, for instance, zinc oxide or magnesium zinc oxide. The method of forming the nanorods 114 on the seed layer 112 is, for instance, hydrothermal synthesis, sol-gel method, metal-organic chemical vapor deposition, chemical vapor deposition, electrodeposition, template method, vapor-liquid-solid method, or vapor phase transport deposition.

In the solar cell 100, since a seed layer 112 and nanorods 114 are formed on the first surface 102a, the reflectance of the solar cell 100 may be effectively reduced.

It should be mentioned that, when the material of the nanorods 114 is magnesium zinc oxide, compared to zinc oxide nanorods, the magnesium zinc oxide nanorods 114 have higher bandgap energy and thus do not absorb light with a wavelength of less than 380 nm, which may increase the amount of incident light with a wavelength of less than 380 nm that enter the substrate 102. Therefore, the efficiency of the solar cell 100 may be further improved.

Referring to FIG. 2E, a protective layer 116 is formed on the nanorods 114 to complete a solar cell 100a. The material of the protective layer 116 is, for instance, compact oxide. The protective layer 116 may be used as a gas and moisture barrier layer to reduce damage to the nanorods 114 caused by moisture and oxygen, as well as suppress corrosion from the outside environment, and may even prevent moisture and oxygen from entering the solar cell 100a and damaging other layers. The material of the protective layer 116 is, for instance, Al₂O₃, AlN, AlP, AlAs, Al_{X}Ti_{Y}O_{Z}, Al_{X}Cr_{y}O_{Z}, Al_{X}Zr_{Y}O_{Z}, Al_{X}Hf_{Y}O_{Z}, Al_{X}Si_{Y}O₂, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, Po_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{y}N_{Z}, Ti_{X}Hf_{Y}O_{Z}, VO_{X}, WO₃, W₂N, W_{X}N, WS₂, W_{X}C, Y₂O₃, Y₂O₂S, ZnS_{1-X}Se_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, or a mixture thereof.

Moreover, since the nanorods 114 have a high aspect ratio, atomic layer deposition (ALD) is needed to form the protective layer 116 in order to effectively cover the surface of each nanorod 114 for a high quality protective layer 116. According to the present embodiment, since the chemical reactions in the ALD process only proceed at the surface of the substrate, the ALD technique exhibits the characteristics of self-limiting and layer-by-layer growth. Accordingly, ALD has the following advantages: (1) the formation of thin films may be controlled at the atomic level; (2) the thickness of the thin films may be precisely controlled; (3) the composition of thin films may be precisely controlled; (4) high uniformity; (5) excellent conformality and step coverage; (6) there is no pinhole structure and defect density is low; (7) large-scale and batch production of the passivation layer is possible; and (8) deposition temperature is lower . . . etc.

According to the present embodiment, since a seed layer 112 and nanorods 114 are formed on the first surface 102a, the reflectance of sunlight is effectively reduced. As a result, the amount of light absorbed by the solar cell 100a is increased, which enhances the photoelectric conversion efficiency of the solar cell 100a. Moreover, in the solar cell 100a, the nanorods 114 are covered by the protective layer 116. The protective layer 116 may reduce corrosion to the nanorods 114 from the outside environment and prevent damage to each layer in the solar cell 100a. Therefore, the reliability of the solar cell 100a is effectively improved.

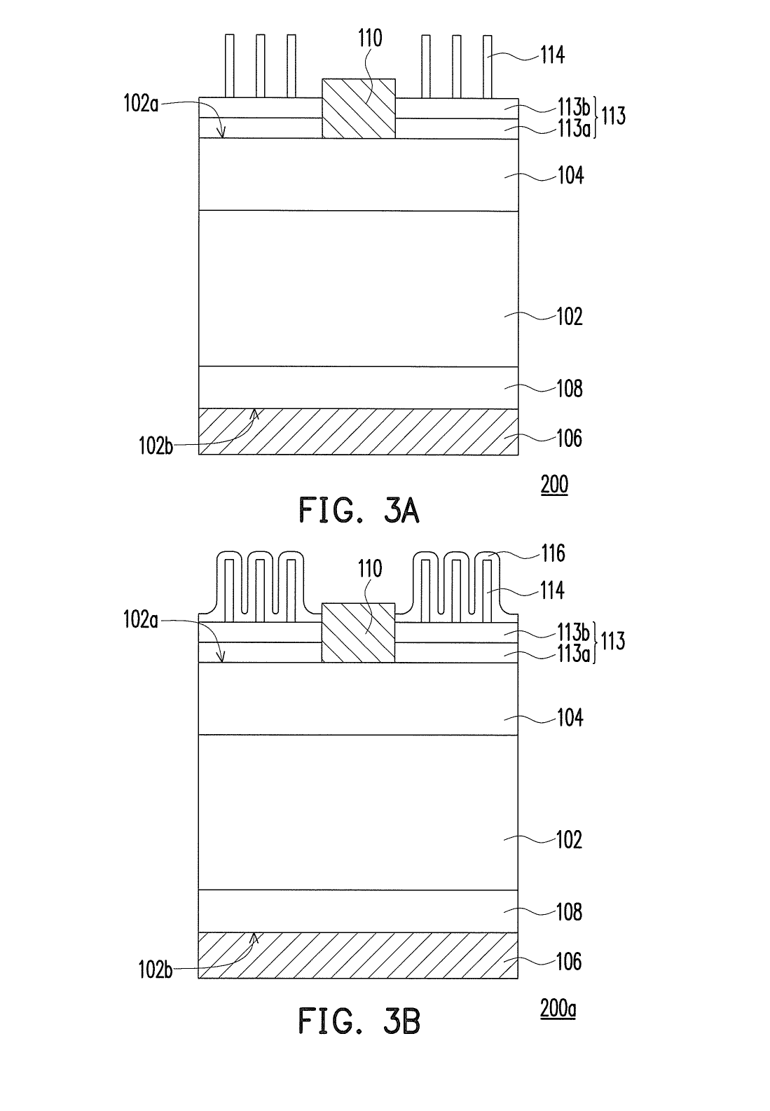

FIG. 3A is a cross-sectional schematic diagram of a solar cell according to another embodiment of the invention. In the present embodiment, the same components of the solar cell 200 and the solar cell 100 are represented by the same reference number. Referring to FIG. 3A, the difference between the solar cell 200 of the present embodiment and the solar cell 100 is: the seed layer 113 in the solar cell 200 of the present embodiment is a composite layer composed of a magnesium oxide buffer layer 113a and a zinc oxide layer 113b. The magnesium oxide buffer layer 113a may effectively improve the crystal quality of the zinc oxide layer 113b to facilitate the growth of the nanorods 114. Specifically, after the step of FIG. 2B is performed, the magnesium oxide buffer layer 113a is formed on the first surface 102a, and the zinc oxide layer 113b is formed on the magnesium oxide buffer layer 113a to complete a seed layer 113. Then, the same step as in FIG. 2D is performed, and a plurality of nanorods 114 are grown on the seed layer 113 to complete a solar cell 200. The method of forming the nanorods 114 on the zinc oxide layer 113b is, for instance, hydrothermal synthesis, sol-gel method, metal-organic chemical vapor deposition, chemical vapor deposition, electrodeposition, template method, vapor-liquid-solid method, or vapor phase transport deposition.

In the solar cell 200, since a seed layer 112 and nanorods 114 are formed on the first surface 102a, the reflectance of the solar cell 200 may be effectively reduced.

It should be mentioned that, when the material of the nanorods 114 is magnesium zinc oxide, since the magnesium zinc oxide nanorods 114 do not absorb light with a wavelength of less than 380 nm, the amount of incident light with a wavelength of less than 380 nm that enter the substrate 102 may be increased. Therefore, the efficiency of the solar cell 200 may be further improved.

Moreover, similar to FIG. 2E, after the nanorods 114 are formed on the seed layer 113, a protective layer 116 may also be formed on the nanorods 114 to complete a solar cell 200a, as shown in FIG. 3B.

According to the present embodiment, since a seed layer 112 and nanorods 114 are formed on the first surface 102a, the reflectance of sunlight is effectively reduced. As a result, the amount of light absorbed by the solar cell 200a is increased, which enhances the photoelectric conversion efficiency of the solar cell 200a. Moreover, in the solar cell 200a, the nanorods 114 are covered by the protective layer 116. The protective layer 116 may reduce corrosion to the nanorods 114 from the outside environment and prevent damage to each layer of the solar cell 200a. Therefore, the reliability of the solar cell 200a is effectively improved.

To confirm that the solar cell of the embodiment of the invention does improve the efficiency of the solar cell, an experimental example is described below. The data results of the experimental example below are only used to explain the measurement results of the efficiency of the solar cell manufactured in an embodiment of the invention, and are not used to limit the scope of the invention.

### Experimental Example 1

A phosphorus diffusion process is performed in step 1. Using a p-type silicon wafer as a substrate, the native oxide layer on the silicon wafer is first removed using BOE (buffer oxide etchants, an aqueous solution containing 30% NH₄F and 6% HF) solution. Then, a phosphorus pentoxide (P₂O₅) solution having an 8% weight concentration is spin coated on the p-type silicon wafer. The spin coating includes two stages. The spinning condition at the first stage is 1,500 rpm for 15 seconds, and the spinning condition at the first stage is 2,500 rpm for 35 seconds, wherein the rate and time of the spin coating determine the thickness and uniformity of the phosphorus pentoxide thin film.

Then, after the spin coating, the silicon wafer is put on a hot plate and heated at 150° C. for 10 minutes, followed by heating at an increased temperature of 200° C. for another 10 minutes. The stability of the thin film containing phosphorus pentoxide is improved by the thermal treatment.

Then, after the thermal treatment, the silicon wafer is put in a tube furnace, and a diffusion process is performed at 900° C. in a nitrogen atmosphere for 30 minutes. As a result, the conductive type of the first surface is n-type, and a p-n junction is formed. After the diffusion process, a SiO₂ layer is also produced on the surface of the silicon wafer.

Afterwards, a BOE solution is used again to remove the SiO₂ on the surface.

A thermal evaporation process of the back electrode is performed in step 2. A layer of aluminum metal is thermally evaporated on the back of the p-type silicon wafer using a thermal evaporator in order to serve as a back electrode, wherein the thickness of the aluminum layer is about 1.2 μm.

Then an annealing process of the back electrode is performed in step 3. The silicon wafer is put in the tube furnace, and an annealing process is performed in an atmospheric ambient having a ratio of 3:1 of nitrogen to oxygen at 600° C. for 25 minutes.

The deposition of the front electrode is performed in step 4. The electrode is thermally evaporated on the front of the silicon wafer using a thermal evaporator. Specifically, 15 nm of nickel is first deposited as an adhesion layer, and then 2.5 μm of silver is deposited to form the front electrode.

The growth of the seed layer is performed in step 5. A zinc oxide thin film (73 nm thick) is grown on the front of the silicon wafer using an ALD technique, wherein the zinc oxide thin film is used as a seed layer. In the ALD process of the zinc oxide thin film, the precursor for zinc is diethylzinc (DEZn, Zn(C₂H₅)₂), and the precursor for oxygen is water vapor.

The nanorod arrays are grown using hydrothermal synthesis in step 6. First, 1.50 g of Zinc nitrate hexahydrate (Zn(NO₃)₂.6H₂O) is dissolved in 500 ml of water (the molar concentration of the zinc ions [Zn²⁺] is about 0.01 M). Then the silicon wafer is put face down in the prepared zinc nitrate solution. Subsequently, 5 ml of 28% ammonia aqueous solution (4NH₃.H₂O, SHOWA) is added to the zinc nitrate solution. A ceramic heating station is used to maintain the temperature of the solution at 95° C., and the rotation speed of the stirring rotor is 95 rpm. The growth is performed in the hydrothermal synthesis for two hours to grow zinc oxide nanorod arrays. After the solar cell of experimental example 1 is completed using the above fabrication processes, the reflectance and efficiency of the solar cell are measured.

### Comparative Example 1

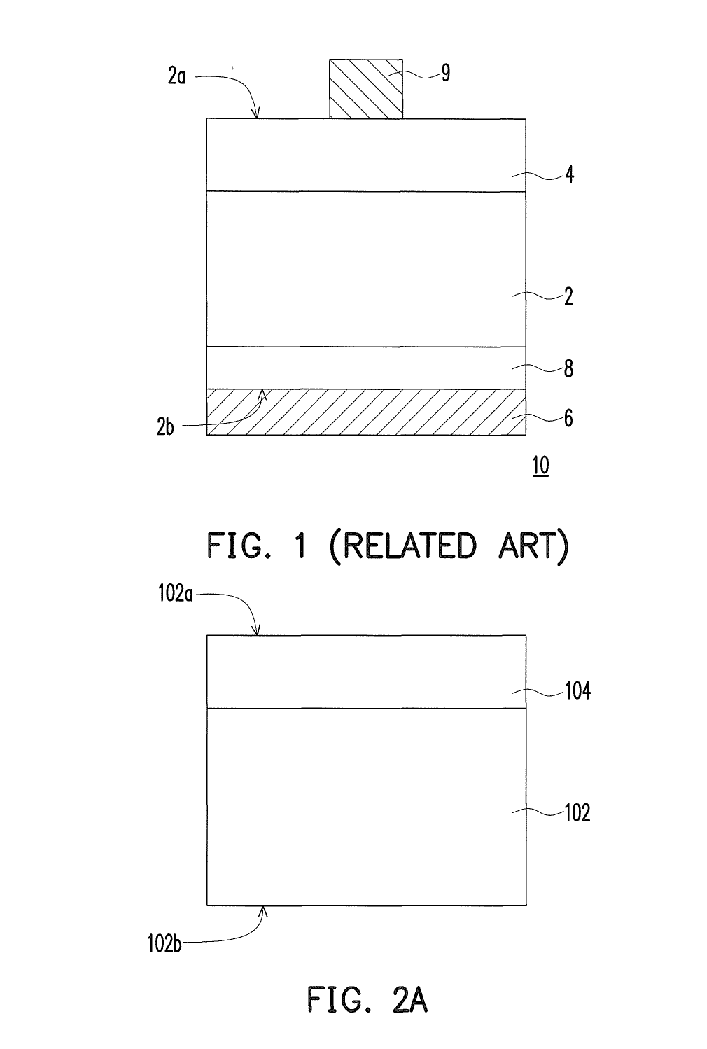

The solar cell of comparative example 1 is formed by performing step 1 to step 4 of experimental example 1, and the structure thereof is as shown in FIG. 1. Specifically, in the solar cell of comparative example 1, a seed layer and nanorod arrays are not formed on the front of the silicon wafer. Finally, the reflectance and efficiency of the solar cell of comparative example 1 are measured.

### Comparative Example 2

The solar cell of comparative example 2 is formed by performing step 1 to step 4 of experimental example 1, and then depositing a zinc oxide layer (73 nm thick) on the front of the silicon wafer, wherein the zinc oxide layer is grown by atomic layer deposition. This zinc oxide layer is used as an antireflection coating layer. Finally, the reflectance and efficiency of the solar cell of comparative example 2 are measured.

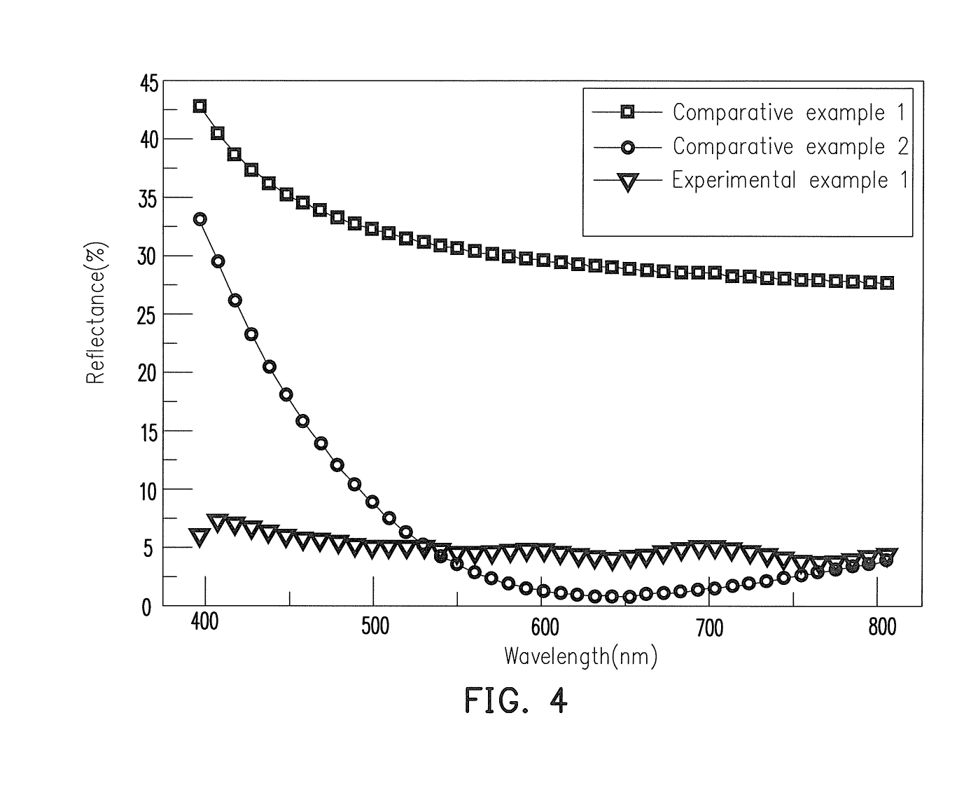

FIG. 4 shows the relationship between the reflectance and the wavelength of incident light of the solar cell of experimental example 1, comparative example 1, and comparative example 2, respectively. It is apparent from FIG. 4 that, the solar cell of experimental example 1 exhibits a low reflectance over a wide wavelength range from 400 nm to 800 nm. Accordingly, by forming a seed layer on the surface of the solar cell and then forming nanorods on the seed layer, the reflectance of sunlight may be effectively reduced over a wide wavelength range from 400 nm to 800 nm. This result indicates that the seed layer and the zinc oxide nanorod array structure may significantly reduce the reflectance of the solar cell. Moreover, the zinc oxide nanorod array structure may also act as a scattering center of the incident light, so that the antireflective effect of the zinc oxide nanorod arrays does not change significantly with respect to different incident angles. As a result, the zinc oxide nanorod arrays contribute a low reflectance in a wide range of sunlight wavelength and a wide range of incident angles. Therefore, the sunlight absorbed by the solar cell may be significantly increased, and the effective power generation time of the solar cell may be lengthened.

Table 1 shows the open-circuited voltage, short-circuited current density, fill factor, and efficiency of the solar cell of experimental example 1, comparative example 1, and comparative example 2, respectively. As compared with comparative example 1 and comparative example 2, the short-circuited current density and efficiency of the solar cell of experimental example 1 are both significantly improved. Specifically, the short-circuited current density is increased from 21.25 mA/cm² to 30.15 mA/cm², and the efficiency is increased from 10.15% to 14.43%.

TABLE 1

| | | Short-Circuited | | |
|---|---|---|---|---|
| | Open-Circuited | Current Density | | efficiency |
| | Voltage (V) | (mA/cm²) | Fill factor | (%) |
| Comparative | 0.550 | 21.25 | 65.14 | 10.15 |
| Example 1 | | | | |
| Comparative | 0.555 | 26.66 | 65.61 | 12.94 |
| Example 2 | | | | |
| Experimental | 0.555 | 30.15 | 64.70 | 14.43 |
| Example 1 | | | | |

### Experimental Example 2

The seed layer of the solar cell of experimental example 2 is composed of a magnesium oxide buffer layer and a zinc oxide layer, wherein the magnesium oxide buffer layer is first formed on the surface of the substrate, and then the zinc oxide layer is formed on the magnesium oxide buffer layer. Then, a plurality of nanorods are formed on the seed layer to complete a solar cell of experimental example 2.

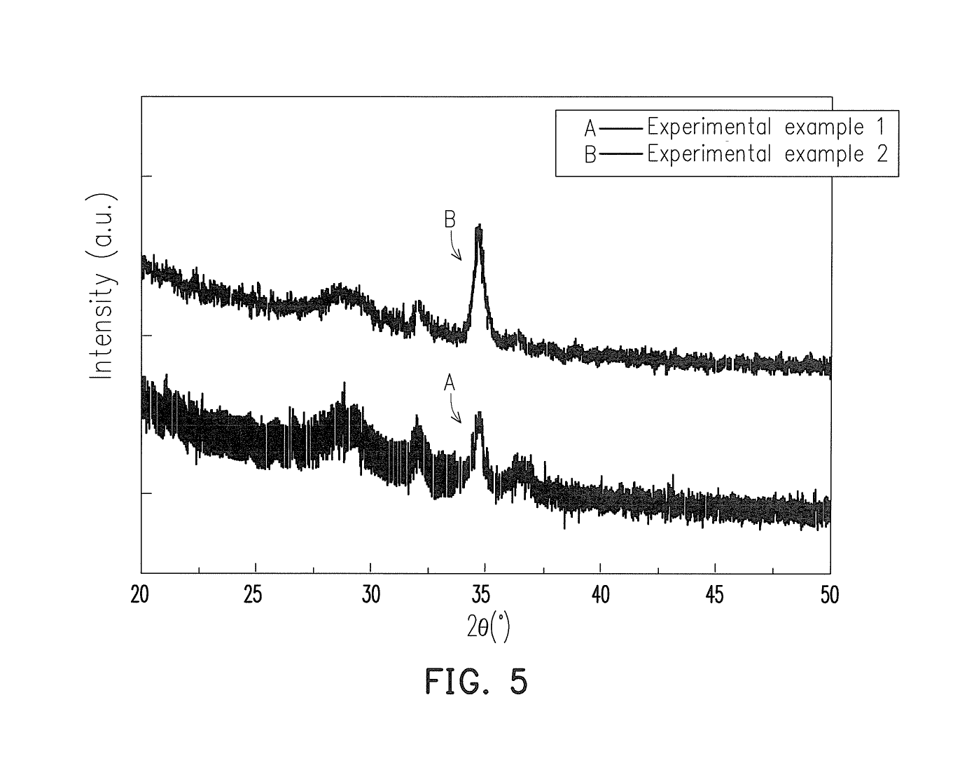

FIG. 5 is an X-ray diffraction spectrum of the solar cell of experimental example 1 and experimental example 2, respectively. Curve A of FIG. 5 represents experimental example 1, curve B represents experimental example 2, wherein the peak at about 35° of 20 is the signal from zinc oxide (0002) orientation. Table 2 shows the full width at half maximum (FWHM) of the zinc oxide (0002) peak of the solar cell of experimental example 1 and experimental example 2, respectively.

TABLE 2

| | Full width at half |
|---|---|
| | maximum (°) |
| Experimental | 0.41 |
| Example 1 | |
| Experimental | 0.33 |
| Example 2 | |

Referring to FIG. 5 and Table 2, it is seen from the X-ray diffraction patterns that, the signal strength of zinc oxide (0002) orientation of the seed layer having a structure containing both a magnesium oxide buffer layer and a zinc oxide layer (experimental example 2) is greater than that of zinc oxide of the seed layer having only a zinc oxide layer structure (experimental example 1). Moreover, the FWHM of the zinc oxide (0002) peak of experimental example 2 is smaller than that of experimental example 1. Therefore, The result indicates that the crystallinity of the zinc oxide nanorod arrays is improved in experimental example 2 due to the insertion of the magnesium oxide buffer layer.

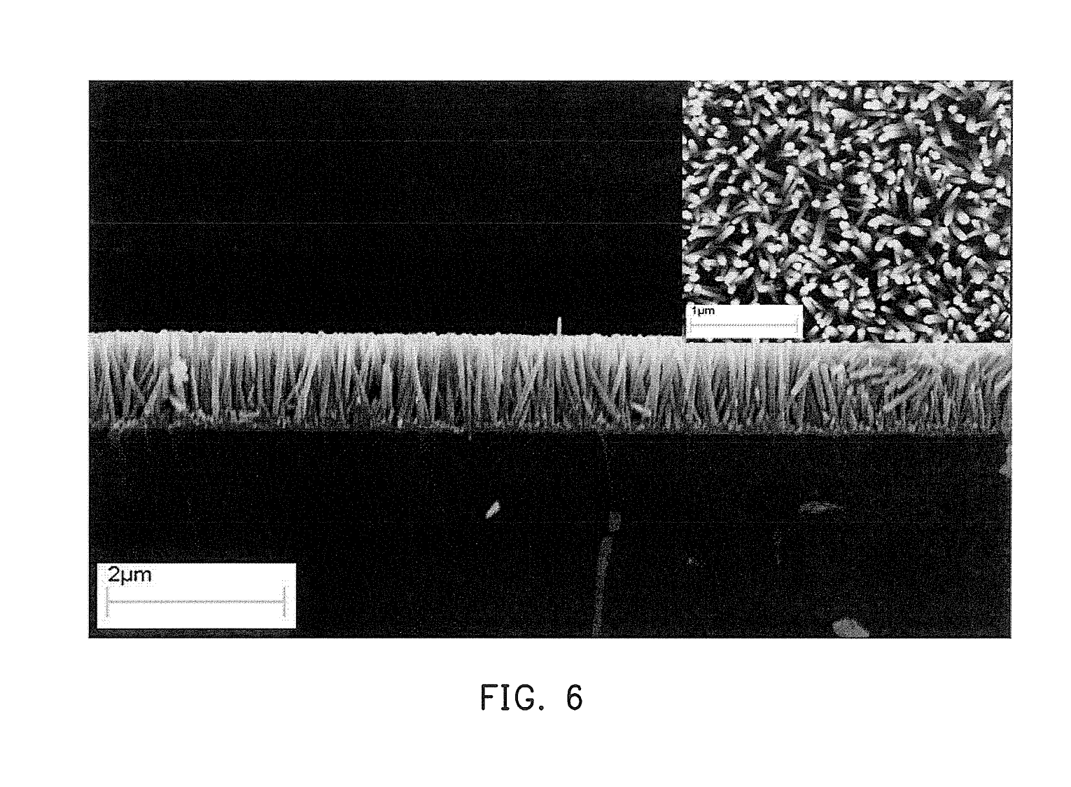

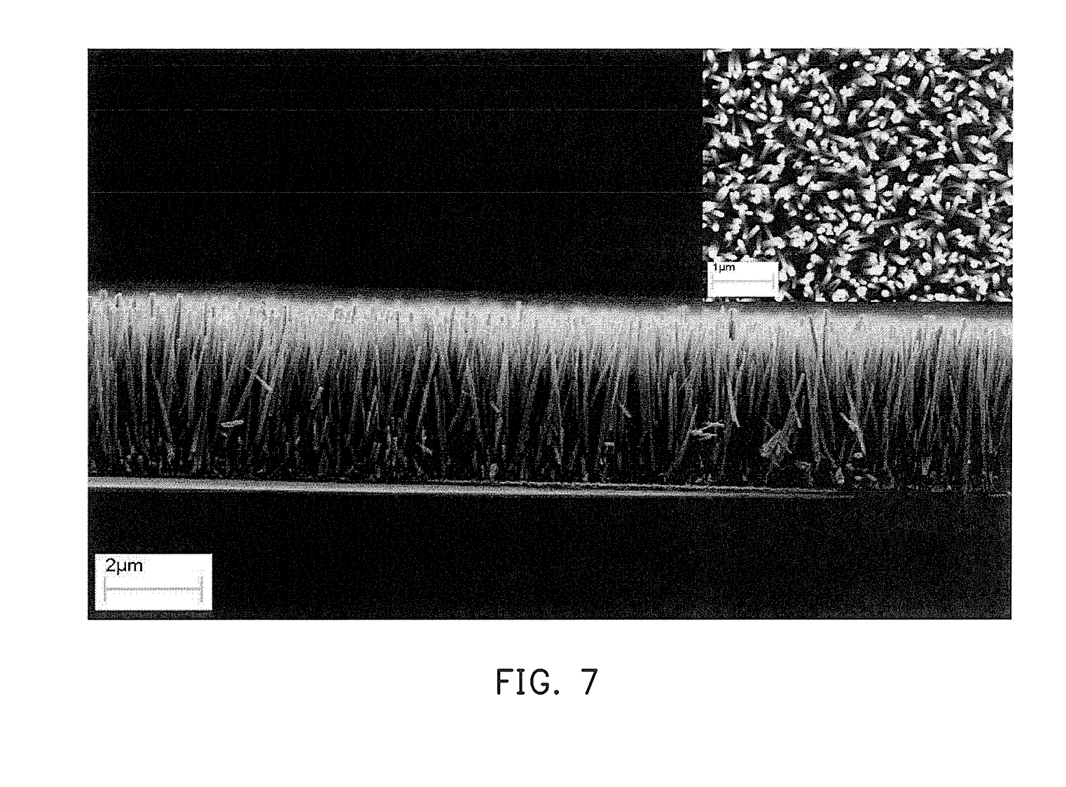

FIG. 6 is a scanning electron microscopy image of a solar cell of experimental example 1. FIG. 7 is a scanning electron microscopy image of a solar cell of experimental example 2. Referring to FIG. 6, the diameter of each zinc oxide nanorod ranges from 90 nm and 110 nm, and the length is about 1.5 μm. Referring to FIG. 7, the diameter of each zinc oxide nanorod ranges from 170 nm and 190 nm, and the length is about 3.7 μm. In other words, the diameter and length of each zinc oxide nanorod of experimental example 2 are greater than the diameter and length of each zinc oxide nanorod of experimental example 1. More specifically, the magnesium oxide buffer layer affects the grain size and crystal quality of the zinc oxide seed layer, and also has a certain degree of influence on the growth of the zinc oxide nanorods.

Based on the above, in the solar cell of the invention, a seed layer is formed on the front surface and nanorods are formed on the seed layer. The seed layer and the nanorods are used as an antireflection structure, so that the reflectance of the solar cell of the invention between the wavelength range from 400 nm to 800 nm is significantly reduced. Therefore, the amount of light absorbed by the solar cell is increased, and thus the efficiency of the solar cell is effectively improved. Moreover, in the invention, a protective layer may be formed on the surface of each nanorod to reduce corrosion to the nanorods from the outside environment and prevent damage to each layer of the solar cell. Therefore, the reliability of the solar cell is further improved.

Although the invention has been described with reference to the above embodiments, it will be apparent to one of the ordinary skill in the art that modifications and variations to the described embodiments may be made without departing from the spirit and scope of the invention. Accordingly, the scope of the invention will be defined by the attached claims not by the above detailed descriptions.

What is claimed is:

1. A solar cell, comprising:
a substrate having a first surface and a second surface opposite to each other, wherein the conductive type of a portion of the substrate adjacent to the first surface is first conductive type, and the conductive type of the rest portion of the substrate is second conductive type;
a first electrode, disposed on the first surface;
a second electrode, disposed on the second surface;
a seed layer, disposed on the first surface; and
a plurality of nanorods, disposed on the seed layer.

2. The solar cell of claim 1, wherein a material of the substrate comprises silicon wafer, thin-film silicon, gallium arsenide, or copper indium gallium selenide (CIGS).

3. The solar cell of claim 1, wherein a material of the seed layer comprises zinc oxide or magnesium zinc oxide.

4. The solar cell of claim 1, wherein the seed layer is composed of a zinc oxide (ZnO) layer and a magnesium oxide (MgO) buffer layer, and the zinc oxide layer is disposed on the magnesium oxide buffer layer.

5. The solar cell of claim 1, wherein a material of the nanorods comprises zinc oxide or magnesium zinc oxide (MgₓZn₁₋ₓO).

6. The solar cell of claim 1, further comprising a protective layer, disposed on a surface of each nanorod.

7. The solar cell of claim 6, wherein a material of the protective layer comprises Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, Po_{X}, P_{X}B_{Y}O_{Z}, RuO, Sc₂O₃, SiO₂, Si₃N₄, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS_{1-X}Se_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, or a mixture thereof.

8. The solar cell of claim 1, wherein the thickness of the seed layer is between 1 Å and 1 μm.

9. The solar cell of claim 1, wherein the nanorods are arranged in an array.

10. The solar cell of claim 1, wherein the seed layer is formed by atomic layer deposition, sputtering, hydrothermal synthesis, sol-gel method, metal-organic chemical vapor deposition, chemical vapor deposition, or electrodeposition.

11. The solar cell of claim 1, wherein the nanorods are formed by hydrothermal synthesis, sol-gel method, metal-organic chemical vapor deposition, chemical vapor deposition, electrodeposition, template method, vapor-liquid-solid method, or vapor phase transport deposition.

12. The solar cell of claim 1, wherein the protective layer is formed by atomic layer deposition.
